(19) United States
(12) Patent Application Publication
(10) Pub. No.: US 2006/0183342 A1
(43) Pub. Date: Aug. 17, 2006

(54) Metal and metal oxide patterned device

(75) Inventors: Roland C. Bruyns, Fairport, NY (US); Cheryl J. Brickey, Webster, NY (US); Robert P. Bourdelais, Pittsford, NY (US); John M. Palmeri, Hamlin, NY (US)

Correspondence Address: Paul A. Leipold;Patent Legal Staff, Eastman Kodak Company, 343 State Street, Rochester, NY, 14650-2201, US

(73) Assignee: Eastman Kodak Company

(21) Appl. No.: 11/057,919

(22) Filed: Feb. 15, 2005

(51) Int. Cl. H01L 21/44

(52) U.S. Cl. 438/768

(57) ABSTRACT

The invention relates to a patterned device comprising a substrate covered by a pattern of metal and oxidized metal surrounding said pattern of metal.

### FIELD OF THE INVENTION

This invention relates to a patterned aluminum and aluminum oxide layer on a substrate, and more particularly relates to a method for forming such a pattern by the selective oxidation of an aluminized web which results in a web covered with aluminum and aluminum oxide in which the pattern of the aluminum is determined by the application of a hydrophobic ink.

### BACKGROUND OF THE INVENTION

Thin patterned films of metal on flexible substrates are useful for many applications. They are especially required for producing inexpensive flexible circuits and also find use in optical films and electronic display devices.

One of the least expensive ways of generating a thin flexible patterned aluminum substrate is to start with an aluminized web and then selectively remove the aluminum from the web. Typically this is done by patterning a resist onto the web and then etching the resist free areas or by depositing a caustic etch in the negative of the desired aluminum pattern and then neutralizing the etch once the desired pattern has been achieved.

U.S. Pat. No. 4,398,994 discloses the formation of a pattern on aluminized web by selective etching of aluminum. In that patent, the pattern is formed on an aluminized polymer film by printing the aluminum surface with a pattern of a caustic resistant masking material such as a water-insoluble resin, contacting the surface with a dilute solution of warm caustic to dissolve the exposed aluminum, and washing the spent solution from the film. While this method produces a patterned aluminum film, the uncovered areas are dissolved leaving bare polymer film. This will result in the water vapor barrier properties of the etched areas being equivalent to that of the uncoated substrate.

U.S. Pat. No. 5,824,456 discloses a method and composition for forming a metal oxide thin film pattern by coating a composition consisting of one or more hydrolitic metallic compounds and a water generating agent which frees water under the effect of UV radiation. The thin film metal oxide pattern is formed by coating the aforementioned composition onto the substrate, irradiating with UV radiation to form an image on the photosensitive film coating and then removing the non-exposed portion by developing in water or alcohol and then heating the substrate to convert the remaining film into a metal oxide. While this method produces a metal oxide thin film pattern, it requires the use of reactive chemicals and does not result in an aluminum pattern in the unreacted areas.

U.S. Pat. No. 4,560,445 (Hoover et al.) discloses a process for fabricating metallic patterns such as resonant RF-tuned circuits on a polyolefin film. The film is processed by being passed through a solvent plasticizing bath, an etch bath, a conditioning bath, and a catalyst bath and it then printed and electroless metal is deposited. This method does create a metallic pattern, but uses many steps with undesirable, reactive chemistries and does not have metal oxide in the non-metal areas to improve vapor and moisture properties of the film.

### PROBLEM TO BE SOLVED BY THE INVENTION

There remains a need for a method to pattern a conductive film and easily convert the area unmasked by hydrophobic material to metal oxide while keeping the patterned area conductive thereby retaining the water vapor barrier properties associated with a fully continuous metal film.

### SUMMARY OF THE INVENTION

It is an object of the invention to provide a flexible conductive patterned substrate.

It is another object to provide a circuit on a polymeric substrate with low vapor transmission rate.

It is a further object to provide a conductive patterned substrate with transparent non-conductive regions.

These and other objects of the invention are accomplished by a patterned device comprising a substrate covered by a pattern of metal and oxidized metal surrounding said pattern of metal.

### ADVANTAGEOUS EFFECT OF THE INVENTION

The invention provides flexible conductive patterned substrate with a low vapor transmission rate and transparent non-conductive regions.

### BRIEF DESCRIPTION OF THE DRAWINGS

FIG. 1 shows a schematic drawing of a substrate with a layer containing a patterned metal circuit surrounded by metal oxide.

FIG. 2 shows a cross sectional schematic of a metal and metal oxide layer overcoated with an insulating layer.

FIG. 3 shows a cross sectional schematic of the metal oxide sections raised above the metal sections.

FIG. 4 shows a cross sectional schematic of a hydrophobic ink layer remaining on the metal.

FIG. 5 shows a cross sectional schematic of a structure that has patterned metal and metal oxide on both sides.

FIG. 6 shows a perspective view of a patterned device containing protuberances.

### DETAILED DESCRIPTION OF THE INVENTION

The invention has numerous advantages compared to current patterning techniques used to construct a flexible conductive patterned surface. This invention produces a patterned metal and complimentary metal oxide pattern by coating a pattern of hydrophobic ink on a pre-existing metal layer coated on a substrate. The substrate is then immersed into a warm water bath, where warm water is defined in this application as water at a temperature of 80° C. or greater; the warm water converts those areas not covered by the hydrophobic ink into metal oxide. The invention provides an inexpensive way to obtain patterned metal films by starting with a continuous metal film that has been applied to any one of several different types of substrates, including polymeric substrates. Some prior art methods for creating an aluminum patterned substrate are limited to silicon or glass because the chemistries for etching are incompatible with polymer substrates. The invention also allows for a patterned film to be obtained from a continuous metallic film without sacrificing the beneficial barrier properties that arise from have a continuous inorganic coating. These and other advantages will be apparent from the detailed description below.

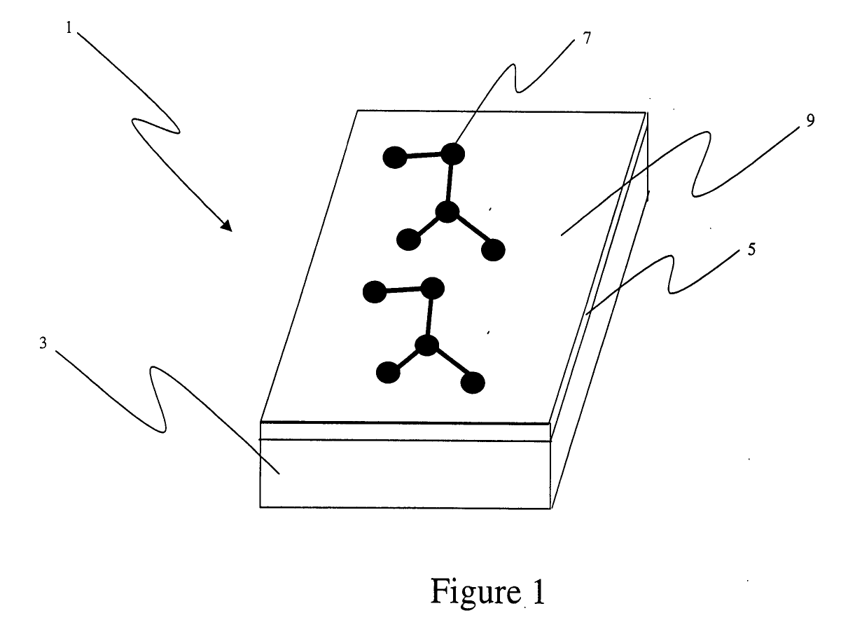

The term “substrate”, in this application is defined as the layer supporting the patterned metal and metal oxide layer. The substrate 3 shown in FIG. 1 could be any flexible or rigid polymer film or flexible or rigid glass. The substrate may or may not be transparent, where the term “transparent”, in this application is defined as having a light transmission of at least 80%. The most preferred percent transmission of the substrate is at least 92% in the case where transparency is preferable. The metal oxide is also transparent using the definition listed above.

The term “pattern” means any predetermined arrangement whether regular or random. In some embodiments of this invention a pattern of hydrophobic material is used to define the pattern of metal. The term “LCD” means any rear projection display device that utilizes liquid crystals to form the image. The term “reflector” means any material that is able to reflect light. The term “diffuse reflector” means any material that is able to reflect and diffuse specular light (light with a primary direction) to a diffuse light (light with random light direction). The term “light” means visible light. The term “total light transmission” means percentage light transmitted through the sample at 500 nm as compared to the total amount of light at 500 nm of the light source. This includes both spectral and diffuse transmission of light. The term “diffuse reflected light” means the percent diffusely reflected light at 500 nm as compared to the total amount of light at 500 nm of the light source. The term “diffuse reflected light efficiency” means the ratio of the percent diffuse reflected light at 500 nm to the percent total reflected light at 500 nm multiplied by a factor of 100. The term “polymeric film” means a film comprising polymers. The term “polymer” means homo- and co-polymers.

FIG. 1 shows a schematic drawing a patterned device 1 which comprises a substrate 3 with a patterned layer 5 on the substrate 3. The patterned layer contains a pattern of aluminum 7 and metal oxide 9. Preferably, the patterned device has the oxidized metal continuously in contact with the edges of the pattern of metal. This means at every point along the outside of the pattern of metal there is oxidized metal and there is no gap between the oxidized metal and metal. This is preferred because if there was a gap between the metal and oxidized metal, the moisture and oxygen barrier properties of the film may be comprised. The oxidized metal is contiguous with the pattern of metal meaning that the metal and oxidized metal are connected.

Preferably the metal used is aluminum, but other metals such as copper, metal alloys, or a mixture of metals could be employed that when exposed to a reactant such as warm water, converts into a thin, transparent, non-conducting layer. Aluminum is preferred because it is inexpensive, easily vacuum deposited into thin, uniform layers, is highly conductive, and in thin layers, reacts with warm or hot water to create aluminum oxide and aluminum hydroxide. In some embodiments, the oxidized metal is aluminum oxide or aluminum hydroxide, which in thin layers is clear, non-conductive, and provides a moisture and vapor barrier. Aluminum hydroxide and selected other metal hydroxides will release water when heated above 180° C. thus providing a level of fire suppression for the film of the invention. The metal is coated onto the substrate using a technique such as sputtering, evaporation or any other method used to deposit metal films. The initial metal coating thickness is preferably less than 5000 angstroms. More preferably, the metal coating is 600 to 1200 angstroms and in some embodiments the thickness is 600 to 800 angstroms. This thickness has been shown to provide sufficient conductivity and reflectivity for both electrical and optical applications while still staying below the thickness limit of metal that can be converted to oxide using warm water. The metal coating is substantially binder free (meaning that there is essentially no binders in the metal coating) and is dense, where the term “dense” in this application refers to a density of greater than 65% of bulk density and preferably greater than 75% of bulk density.

Preferably, the substrate is polymeric, transparent, and flexible. In one embodiment, the substrate is a biaxially stretched and heat stabilized polyester such as poly(ethylene terephthalate)(PET), or poly(ethylene naphthalate)(PEN). PET or PEN are preferred because they have good dimensional stability and high durability. Preferred polymers also include oriented polyolefin such as polyethylene and polypropylene, cast polyolefins such as polypropylene and polyethylene, polystyrene, acetate and vinyl. Polyolefins are low in cost and have good strength and surface properties. In another embodiment of the invention the substrate comprises a cellulose acetate. Tri acetyl cellulose has both high optical transmission and low optical birefringence. In another embodiment of the invention the substrate comprises polycarbonate. Polycarbonates have high optical transmission values and are also tough and durable. Polycarbonates are available in grades for different applications and some are formulated for high temperature resistance, excellent dimensional stability, increased environmental stability, and lower melt viscosities. A flexible substrate allows for the creation of flexible circuits.

Preferably, the oxidized metal and the substrate are transparent. This enables the invention to be used in applications needing high levels of transparency outside of the metal conductive pattern, such as liquid crystal displays or any other electric display or pixilated display. Having the oxide and substrate transparent may also allow the invention to be used as Electro Magnetic Interference (EMI) shielding.

The term conductive means the ability of a material to conduct electrical current. Conductivity is the reciprocal of resistivity. Resistivity is measured in units of ohms/square, this measurement is unitless A common way of referring to surface resistance of a conductive layer coated on a substrate is by the term surface electrical resistance or SER. SER is measured in units of ohms/square. Conductive materials utilized in this invention generally have resistivity of less than 30 ohms/square. This range has been shown to create patterns of metal that can be used in display applications.

Preferably, the resistivity of the oxidized metal is at least 2000 ohms/square. When the resistivity is less than 900 ohms/square, the film could not be used in some applications because of the current leakage would be too large. More preferably, the resistivity of the oxidized metal is at least 5,000 ohms/square. It has been shown that this level of resistivity produces sufficient isolation of the pattern of metal and low losses due to current leakage from the pattern of metal to the oxided metal.

Preferably, the patterned metal has a specular visible light reflectivity of at least 80%. The patterned device was measured with the Hitachi U4001 UV/Vis/NIR spectrophotometer equipped with an integrating sphere. The total transmittance spectra were measured by placing the samples at the beam port with the front surface with complex lenses towards the integrating sphere. The beam port used was 2.54 centimeters. A calibrated 99% diffusely reflecting standard (NIST-traceable) was placed at the normal sample port. The diffuse transmittance spectra were measured in like manner, but with the 99% tile removed. The diffuse reflectance spectra were measured by placing the samples at the sample port with the coated side towards the integrating sphere. The total reflectance spectra were measured by placing the samples at the sample port with the patterned layer towards the integrating sphere and the incoming light at an angle. In order to exclude reflection from a sample backing, nothing was placed behind the sample. All spectra were acquired between 350 and 800 nm. As the reflectance results are quoted with respect to the 99% tile, the values are not absolute, but would need to be corrected by the calibration report of the 99% tile. Diffuse reflectance is defined as the percent of light reflected by the sample and reflected more than 2.5 degrees.

In one embodiment, the pattern of metal has a specular visible light reflectivity of at least 80%. This means that at least 80% of the light at 500 nanometers is specularly reflected off the metal, being scattered less than 2.5 degrees as it reflects off the surface of the pattern of metal. This has been shown to provide adequate reflectivity in some applications where a specular reflection is desired such as a circuit for an LCD where it is desired to not have the light reflected off the circuit diffused.

In another embodiment the diffuse visible light reflectivity is at least 80%. This means that at least 80% of the light at 500 nanometers is specularly reflected off the metal, being scattered more than 2.5 degrees as it reflects off the surface of the pattern of metal. This has been shown to be preferable in other applications where it is preferable to have light diffusely reflected off a surface such as some recycling systems for liquid crystal displays.

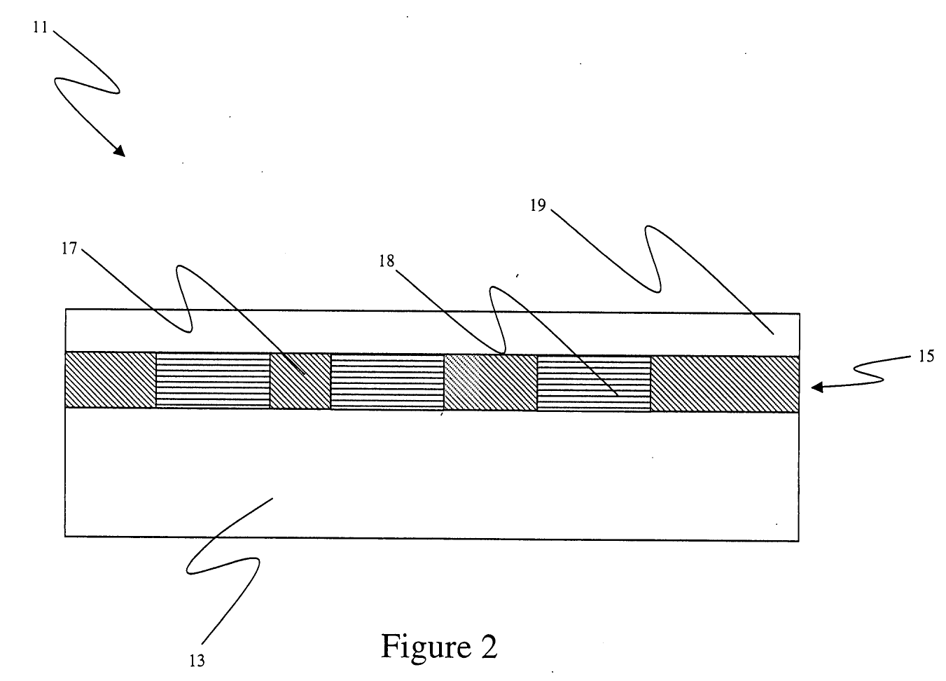

FIG. 2 shows a cross-sectional schematic view of a patterned device 11 showing a substrate 13 with a patterned layer 15 containing metal oxide 17 and metal 18 overcoated with an insulating layer 19. The overcoat layer 19 may be used to provide added utility to the invention including, but not limited to scratch resistance, surface smoothing or protection of the substrate and film from environmental factors. The overcoat is preferably applied to the patterned device on top of the layer containing the metal and metal oxide. In one embodiment the overcoat may be a hardcoat layer. Abrasion resistant or hard coatings will frequently be applied as a skin layer. These include acrylic hardcoats such as Acryloid A-11 and Paraloid K-120N, available from Rohm & Haas, Philadelphia, Pa.; urethane acrylates, such as those described in U.S. Pat. No. 4,249,011 and those available from Sartomer Corp., Westchester, Pa.; and urethane hardcoats obtained from the reaction of an aliphatic polyisocyanate (e.g., Desmodur N-3300, available from Miles, Inc., Pittsburgh, Pa.) with a polyester (e.g., Tone Polyol 0305, available from Union Carbide, Houston, Tex.).

The overcoat may also be a pressure sensitive adhesive. The pressure sensitive adhesive is used to adhere the patterned device onto an object, such as an ID badge, display component or other film. The adhesive preferably is coated or applied to the device. A preferred pressure sensitive adhesive is an acrylic-based adhesive. Acrylic adhesives have been shown to provide an excellent bond between plastics. The preferred adhesive materials may be applied using a variety of methods known in the art to produce thin, consistent adhesive coatings. Examples include gravure coating, rod coating, reverse roll coating and hopper coating.

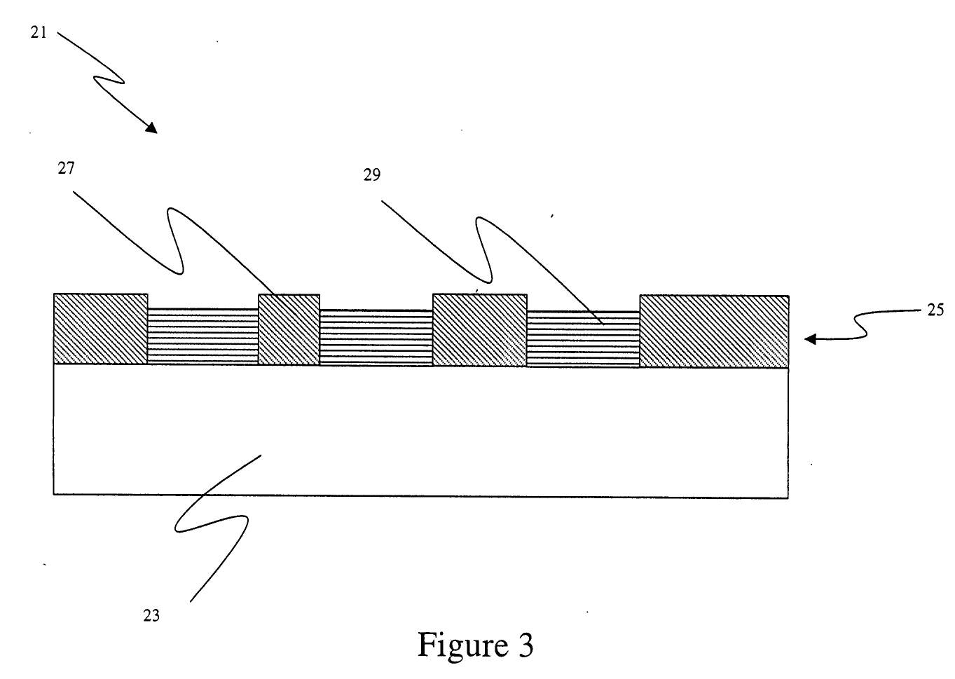

FIG. 3 shows a cross sectional schematic of the patterned device with metal oxide sections extending above the metal sections. The patterned device 21 contains a substrate 23 with a patterned layer 25 containing metal oxide 27 and a metal 29. The height difference in the metal 19 and metal oxide 17 results from the volume expansion of the metal when it undergoes oxidation. This height difference of between 10 and 30 percent of the metal layer is preferable in some embodiments because it provides protection to the recessed conductive and reflective metal pattern from abrasion and defects that may be caused if the metal were to contact the backside of the substrate when the substrate in is a wound roll format.

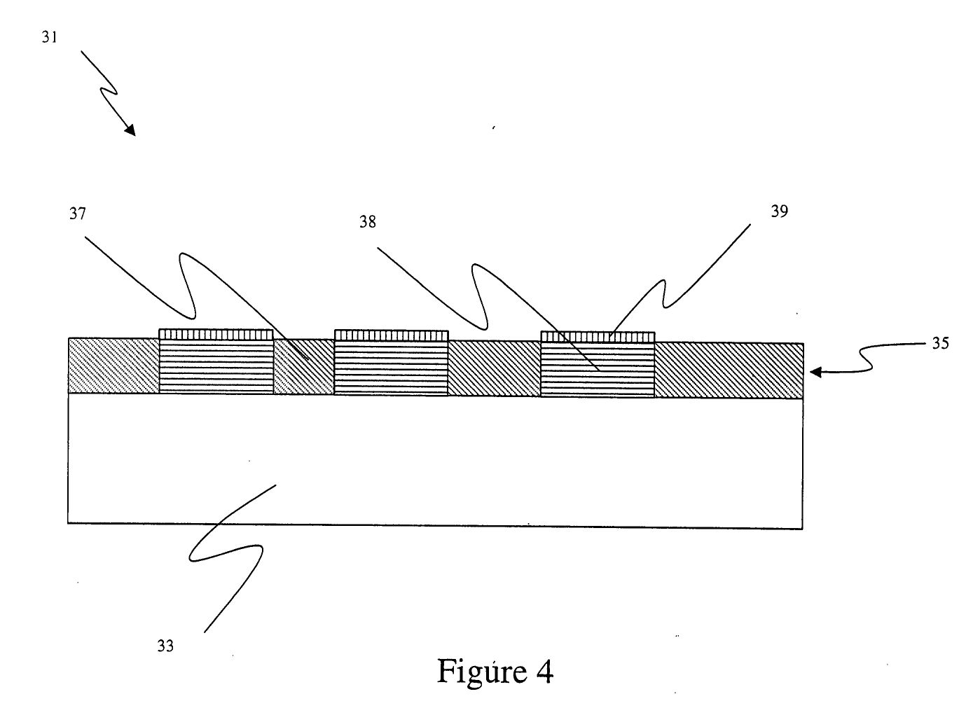

FIG. 4 shows a cross-sectional schematic view of a patterned device 31 showing a substrate 33 with a patterned layer 35 containing metal oxide 37 and metal 38 wherein the metal is coated with a hydrophobic material 39.

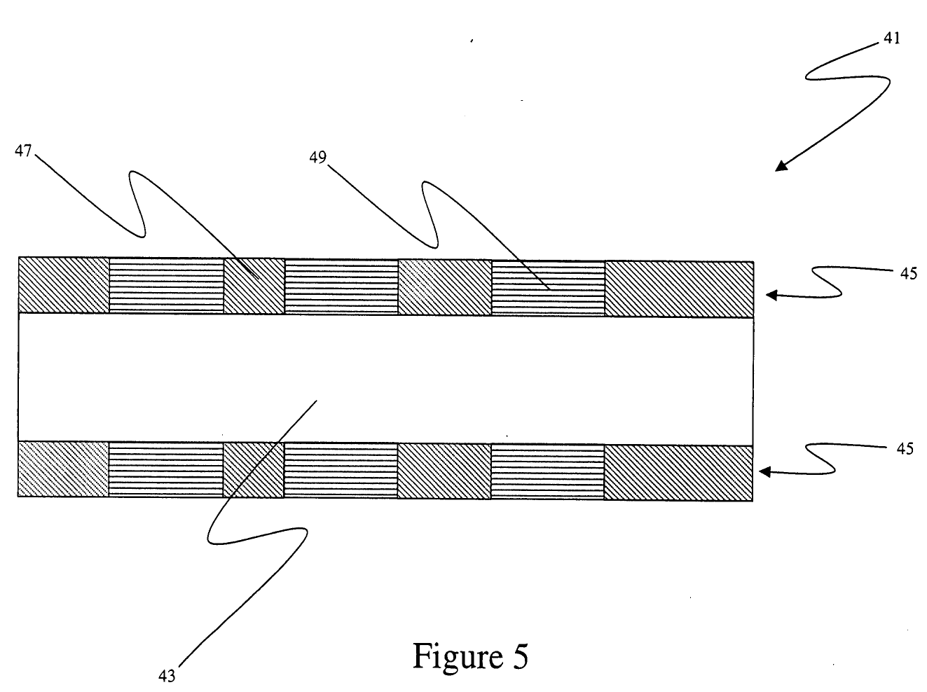

FIG. 5 shows a cross sectional schematic of a patterned device 41 showing a substrate 43 with a patterned layers 45 on wither side of the substrate 43. The patterned layers 45 contain metal oxide 47 and metal 49. In some cases it may be advantageous to have patterned metal on both sides of the substrate because this allows an increase in the components that can be placed without a need to increase the area being used.

The invention allows for a patterned film to be obtained from a continuous metallic film without sacrificing the beneficial barrier properties that arise from have a continuous inorganic coating. Having a continuous inorganic coating yields water and oxygen barrier properties that are important to many flexible conductive layer applications. Barrier coatings (such as the continuous inorganic coating of the invention) are used on flexible polymer films to reduce the water vapor transmission rate (WVTR) and the oxygen transmission rate (OTR) through the polymer film. The most common barrier coating material is aluminum, which is deposited on rolls of polymer film (web). In some cases the metal coatings are deposited on a surface and then “transferred” to the packaging film. Layers of some inorganic oxides are used to form transparent barrier layers.

Preferably, the layer containing the metal and metal oxide has a water vapor transmission rate of less than 0.4 g/m²/day. Having a low water transmission rate is important to electronic and displays where water can corrode and damage electronics, such as displays or circuits. The water transmission rate can be determined from analytical equipment such as the MOCON W3/31 Water Vapor Permeability.

Preferably, the oxygen transmission rate through the layer containing the metal and metal oxide is less than 50 cc/(m²*day). It has been shown that this OTR is required for some electronic applications. The oxygen transmission rate can be determined from analytical equipment such as the MOCON Ox-Tran 2/21 Oxygen Permeability, MOCON Ox-Tran 2/20 Oxygen Permeability, or the Oxtran 100-twin.

FIG. 4 shows a cross-sectional schematic view of a patterned device 31 showing a substrate 33 with a patterned layer 35 containing metal oxide 37 and metal 38 wherein the metal is coated with a hydrophobic material 39. The hydrophobic material is on top of the metal on the side of the metal opposite to the substrate. The hydrophobic material serves to pattern the metal layer and protect the pattern of metal from being converting into the metal oxide when the film is reacted in warm water. The hydrophobic material may be any material that can be applied pattern-wise to the metal layer and is hydrophobic, such as many commercially available solvent-based inks. The hydrophobic material can be applied by any method, for example inkjet, flexo printing, gravure printing, screen printing, electrophotography, and thermal printing (including thermal dye sublimation), and pen.

In one embodiment, flexography is preferred. Flexography is an offset letterpress technique where the printing plates are made from rubber or photopolymers. The rotogravure method of printing uses a print cylinder with thousands of tiny cells that are below the surface of the printing cylinder. The ink is transferred from the cells when the print cylinder is brought into contact with the pressure sensitive label at the impression roll. Printing inks for flexography or rotogravure include solvent based inks, water based inks, and radiation cured inks all of which can be hydrophobic.

In another embodiment, inkjet printing is preferred because inkjet can used digital files and can change what is printed piece to piece. Inkjet is also relatively inexpensive, can be printed roll to roll, and can be printed quickly. Ink jet printing is a non-impact method for producing images or patterns by the deposition of ink droplets in a pixel-by-pixel manner to an element in response to digital signals. Continuous ink jet and drop-on-demand inkjet are examples of methods that may be utilized to control the deposition of ink droplets to yield the desired image.

Pens can be used to freehand the patterns using a hydrophobic ink. This is useful for simple patterns to be tested without the need for printing apparatuses.

In another embodiment, the hydrophobic material can be transferred to the metal layer using thermal transfer. Thermal transfer is preferred because the file is digital meaning that every print can be different and thermal printing can be produced roll to roll. The hydrophobic material would be coated on a thin donor web that may include release layers and/or slip layers and heat and or pressure would be used to transfer the hydrophobic material onto the metal layer of the device.

The transfer element for transferring the hydrophobic material preferably comprises a thermally activated release layer on the donor web. Thermally activated release layers are typically polymer layers having a Tg less than the transfer temperature. Upon thermal transfer, the thermally activated release layer flows, breaking the bond between the transfer layer and the base. It has been shown that when a thermally activated release layer is utilized, the Tg of the thermally activated layer should be less than the Tg of the transfer layer polymer matrix. This allows for high transfer efficiency and while maintaining the mechanical integrity of the transfer layer.

In some cases it may be preferable to leave the hydrophobic ink in place after oxidation of the unmasked areas. This may save a processing step, if it is not necessary to have a bare metallic surface on the top of the substrate film structure. In another embodiment it may be preferable to leave the ink in place so the pattern is only reflective when viewed through the bottom of the transparent substrate. In embodiments where it is important to have the pattern of metal reflective from both sides of the patterned device, the hydrophobic material is preferably removed. For example, if the hydrophobic material was a solvent-based ink, an application of rubbing alcohol will remove the thin hydrophobic layer.

Conductive patterns, consisting of lines and shapes, applied to the surface of a flexible substrate, can be utilized for a variety of flexible, conductive applications. By reducing the line width or the size of the conductive shape, the flexible pattern can be made smaller allowing for small and more efficient electrical devices. In one embodiment, the pattern of metal has an average line width of between 15 micrometers and 5 millimeters. Below 10 micrometer line width is limited by the resolution of the printing method and above 6 millimeters, there is a diminishing increase in conductivity of the lines as the width increase.

This invention produces a patterned metal and complimentary metal oxide pattern by coating a pattern of hydrophobic ink on a pre-existing metal layer coated on a substrate. The substrate is then immersed into a warm water bath and the warm water converts those areas not covered by the hydrophobic ink into metal oxide. An aqueous bath is preferred because the conversion of metal to the metal oxide is carried out without harmful or expensive solvents.

The time required for conversion will depend on the thickness of the metal and the temperature of the warm water bath. Preferably the temperature of the bath is at a temperature of 80° C. or greater, more preferably at a temperature of between 80 to 100° C., to reduce the time required to convert the metal to metal oxide. Preferably the pH of the bath is between 4 and 6 because this has been shown to be the pH at which the dissolution of the aluminum oxide by the aqueous bath will be the slowest. Because no material is removed, it is instead oxidized to aluminum oxide. The oxidation product may be aluminum hydroxide because the oxidation occurs in an aqueous environment but it can be dehydrated by heating to 180° C. or higher. The presence of the oxidized metal ensures that the moisture barrier properties inherent to an inorganic coated polymer substrate are preserved. Being able to produce patterned metal from a thin continuous film of metal allows for the manufacture of several different types of devices, including an antenna, flexible electric circuit, optical grating, transreflector, and optical mask. The invention may also be used to create formed birefringence resulting in a reflective polarizer. Electrically patterned elements on flexible substrates can be used for membrane switches, radio frequency labels, EMI shielding, flexible circuits, electrical connections, flexible photovoltaic cells and liquid crystal TFT arrays.

In one embodiment of the invention the patterned metallic areas are designed to act as a light management film. Additional layers preferably are added to the light management film that may achieve added utility. Such layers might contain tints, antistatic materials, or different void-making materials to produce sheets of unique properties.

The optical films and electronic devices of the present invention may further be laminated to rigid or semi-rigid substrates, such as, for example, glass, metal, acrylic, polyester, and other polymer backings to provide structural rigidity, weatherability, or easier handling. For example, the electronic devices of the present invention may be laminated to a thin acrylic or metal backing so that it can be stamped or otherwise formed and maintained in a desired shape.

In another embodiment of the invention, the patterned device comprises colorants. The colorants can be in the substrate, in the hydrophilic material, or printed onto the pattern of metal and/or the metal oxide. Colorants are useful because they can allow for easy visual assessment of the transferred hydrophobic material. Further the colored layer can be used to differentiate multiple utilities in patterned conductive element. For example, input conductive patterns can be colored red and output conductive patterns can be colored blue. Colorants may comprise dye, pigments or mixtures thereof.

In one embodiment of the invention, the substrate has protuberances on the surface of the substrate in which the metal is deposited. The protuberances' aspect ratio, placement, and height should be chosen such that the entire surface area of the substrate is deposited with metal. When the hydrophobic material is printed onto the metal layer using some printing techniques, such as thermal printing, the hydrophobic material will only transfer to the highest points of the substrate and not print in the areas between the protuberances. Using thermal printing techniques protuberances located on the surface of the flexible substrate allow for the hydrophobic materials to be transferred to the upper most portion of the protuberances while little or no materials are transferred to the valleys or lower most portions of the protuberances. Having an average protuberance height less than 5 micrometers does not adequately ensure that the hydrophobic materials are located on the top surface of the protuberances in all thermal transfer systems. A thermal printer requires very smooth media in which to print a uniform layer; if there are pits or low points in the media, dyes or hydrophobic materials are not transferred to that pit (or non-protrusion areas). A thermal printer (using heat and/or pressure or lasers) can transfer the hydrophobic material only to the protrusions to make them hydrophobic and leave the rest of the individual elements unprinted and therefore will convert to metal oxide when exposed to warm water.

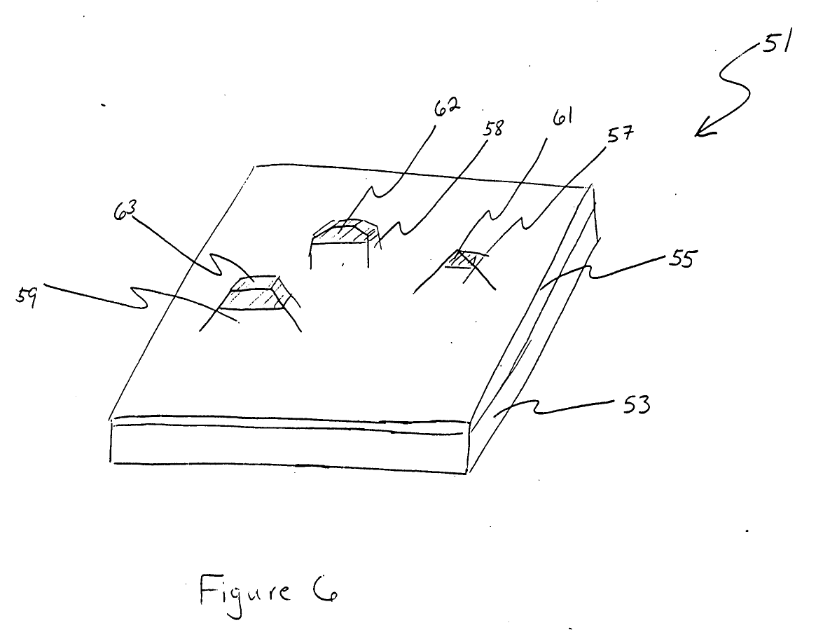

FIG. 6 shows a schematic of a patterned device 51 showing a substrate 53 containing protuberances 57-59 and covered by a layer of metal 55 on one side of the substrate 53. The protuberances 57-59 are conformably coated with the layer of metal 55. The protuberances 57-59 can be any three dimensional shape preferably greater than 5 microns in heights. A hydrophobic material 61-63 is transferred to the uppermost portion of the protuberances 57-59.

Protuberances comprising surface microstructures are preferred. Microstructures can be tuned for different light shaping and spreading efficiencies and how much they spread light and are three-dimensional. The protuberances can be discrete or continuous and may be a circuit-like pattern. Examples of microstructures are a simple or complex lenses, prisms, pyramids, posts, linear arrays and cubes. The shape, geometry, and size of the microstructures can be changed to accomplish the desired light shaping. The surface microstructure can comprise any surface structure, whether ordered or random. The microstructure can be a linear array of prisms with pointed, blunted, or rounded tops or sections of a sphere, prisms, pyramids, and cubes. The protuberances discrete or continuous and can be random or ordered, and independent or overlapping. The sides can be sloped, curved, or straight or any combination of the three. The protuberances can be individual optical elements varying in shape, size, location or frequency over the substrate.

When the protuberances are metallized, the entire structure, or almost the entire structure is coated with a metallic layer. Different operations to selectively transfer the hydrophobic material may be employed such as thermal transfer. When thermal transfer is used, the thermal printer has difficulty printing the entire surface area of the protuberance (because of the high of the protuberance), instead coating only the top section of the protuberance. This way the tops of the protuberances are protected and when washed with water, the rest of the protuberance and the surrounding substrate are converted into metal hydroxide. This is desirable because to create a pattern of reflective and non-reflective areas (or conductive and nonconductive areas) one can create the desired pattern using the protuberances and then use the thermal printer to blanket print the entire sheet (but the material will only be able to transfer to the top sections of the protuberances), thus creating the pattern of metal easily, inexpensively, and with high precision. Therefore, the resolution of the pattern created is dependant on the resolution of the protuberance placement and geometry.

In a preferred embodiment of the invention, the protuberances have a height of between 10 and 1000 micrometers, more preferably between 10 and 100 micrometers. Protuberance heights greater than 1100 micrometers are difficult to integrate into a flexible substrate, further these protuberances are difficult to wind into a roll and therefore are not economical.

The following example illustrates the practice of this invention. They are not intended to be exhaustive of all possible variations of the invention. Parts and percentages are by weight unless otherwise indicated.

### EXAMPLE

A flexible, biaxially oriented PET film was used as the substrate for the patterned device. It was approximately 100 micrometers thick PET film known commercially as Estar with a transmission of 81%. The substrate was then coated with aluminum. A DC magnetron sputter gun was used to deposit 700 angstroms of aluminum onto the substrate. The sputtering was done at 5 mT in an argon atmosphere.

The aluminum coated piece of PET was then patterned with a simple circuit design with a commercially available solvent-based ink commercially available as Sharpie® permanent black marker. The ink consisted of dyes in a solvent solution of n-propanol (71-23-8), n-butanol (71-36-3) and diacetone alcohol (123-42-2). Once the ink was dry the sample was immersed into a water bath at 90° C. for 1 minute. The time was sufficient to convert the unmasked area to aluminum oxide. Once the conversion was complete, the ink was removed by rinsing the surface with acetone. The resulting patterned device had a pattern of metal with a reflectivity of 87% and areas of aluminum oxide with a transmission of 85%. The pattern of metal had mostly specular reflectivity.

The invention has been described in detail with particular reference to certain preferred embodiments thereof, but it will be understood that variations and modifications can be effected within the spirit and scope of the invention.

### PARTS LIST

1; Patterned device
3; Substrate
5; Patterned layer
7; Aluminum
9; Aluminum oxide
11; Patterned device
13; Substrate
15; Patterned layer
17; Metal oxide
18; Metal
19; Insulating layer
21; Patterned device
23; Substrate
25; Patterned layer
27; Metal oxide
29; Metal
31; Patterned device
33; Substrate
35; Patterned layer
37; Metal oxide
38; Metal
39; Hydrophobic material
41; Patterned device
43; Substrate
45; Patterned layer
47; Metal oxide
49; Metal
51; Patterned device
53; Substrate
55; Metal layer
57-59; Protuberances
61-63; Hydrophobic material

1. A patterned device comprising a substrate covered by a pattern of metal and oxidized metal surrounding said pattern of metal.

2. The patterned device of claim 1 wherein said oxidized metal is continuously in contact with the edges of the pattern of metal.

3. The patterned device of claim 1 wherein said oxidized metal is contiguous with the pattern of metal.

4. The patterned device of claim 1 wherein said metal comprises aluminum.

5. The patterned device of claim 4 wherein said oxidized metal comprises aluminum oxide.

6. The patterned device of claim 1 wherein said oxidized metal comprises aluminum hydroxide.

7. The patterned device of claim 1 wherein said oxidized metal and said substrate are transparent.

8. The patterned device of claim 1 wherein said pattern of metal has a resistivity of less than 30 ohms/square.

9. The patterned device of claim 1 wherein said oxidized metal has a resistivity of greater than 2000 ohms per square.

10. The patterned device of claim 1 wherein said pattern of metal has a specular visible light reflectivity of at least 80%.

11. The patterned device of claim 1 wherein said substrate comprises a flexible polymer sheet.

12. The patterned device of claim 1 wherein said pattern of metal has a diffuse visible light reflectivity of at least 80%.

13. The patterned device of claim 1 wherein said device further comprises an insulating layer on the opposite side of said substrate from the pattern of metal and oxidized metal.

14. The patterned device of claim 1 wherein said pattern of metal and the oxidized metal have a height difference of between 10 and 30% and said pattern of metal is of lower height than said oxidized metal.

15. The patterned device of claim 1 wherein the pattern of metal and oxidized metal has an oxygen transmission rate of less than 50 cc/(m²*day).

16. The patterned device of claim 1 wherein the pattern of metal and oxidized metal has a water vapor transmission rate of less than 0.4 g/(m²*day)

17. The patterned device of claim 1 wherein said pattern of metal is substantially binder-free.

18. The patterned device of claim 1 wherein said pattern of metal comprises a hydrophobic material on the side opposite to the substrate.

19. The patterned device of claim 1 wherein said pattern of metal has a thickness of less than 5000 angstroms.

20. The patterned device of claim 1 wherein said pattern of metal has a thickness of between 600 and 800 angstroms.

21. The patterned device of claim 1 wherein said device is covered on both sides by a pattern of metal and oxidized metal surrounding said pattern of metal.

22. The patterned device of claim 1 wherein said pattern of metal has an average line width of between 15 microns and 5 millimeters.

23. The patterned device of claim 1 wherein said device is an antenna.

24. The patterned device of claim 1 wherein said device is a flexible electrical circuit.

25. The patterned device of claim 1 wherein said device is an optical grating.

26. The patterned device of claim 1 wherein said device is a transreflector.

27. The patterned device of claim 1 wherein said device is an optical mask.

28. A method of forming a patterned device comprising providing a substrate having a continuous metal layer, applying a pattern of hydrophobic material to said metal layer, and converting the area not covered by said pattern of hydrophobic material to said metal oxide.

29. The method of claim 28 wherein converting is in an aqueous bath.

30. The method of claim 28 wherein said bath is at a temperature of between 80 and 100° C.

31. The method of claim 28 wherein said bath has a pH of between 4 and 6.

32. The method of claim 28 wherein applying a hydrophobic material is by printing.

33. The method of claim 28 wherein applying a hydrophobic material is by inkjet.

34. The method of claim 28 wherein applying a hydrophobic material is by thermal transfer.

35. The method of claim 28 wherein applying a hydrophobic material is by pen.

36. The method of claim 28 further comprising removing said hydrophobic material.

37. The method of claim 28 wherein said metal layer comprises aluminum.

38. The method of claim 28 wherein said metal oxide comprises aluminum oxide.

39. The method of claim 28 wherein said metal oxide and said substrate are transparent.

40. The method of claim 28 wherein said patterned device has a water vapor transmission rate of less than 0.4 g/(m²*day).

41. The method of claim 28 wherein said metal layer is substantially binder-free.

42. The method of claim 28 wherein said metal layer has a resistivity of less than 30 ohms/square.

43. The method of claim 28 wherein said metal layer has a thickness of less than 5000 angstroms.
